(19) United States
(12) Patent Application Publication
(10) Pub. No.: US 2014/0076842 A1
(43) Pub. Date: Mar. 20, 2014

(54) DRY ETCHING METHOD AND DEVICE MANUFACTURING METHOD

(71) Applicant: FUJIFILM Corporation, Tokyo (JP)

(72) Inventor: Shuji TAKAHASHI, Kanagawa (JP)

(73) Assignee: FUJIFILM Corporation, Tokyo (JP)

(21) Appl. No.: 14/082,756

(22) Filed: Nov. 18, 2013

Related U.S. Application Data
(63) Continuation of application No. PCT/JP2012/062368, filed on May 15, 2012.

(30) Foreign Application Priority Data
May 20, 2011 (JP) 2011-113627

(51) Int. Cl. H01L 41/39

(52) U.S. Cl. CPC H01L 41/39
USPC 216/13

(57) ABSTRACT

A dry etching method of etching a conductive material layered on a dielectric material, comprising: using a mixed gas including a halogen gas and an oxygen gas as an etching gas, a mixing ratio of the oxygen gas in the mixed gas being equal to or greater than 30% and equal to or less than 60%; setting a gas pressure in a chamber at a time of supplying the mixed gas into the chamber and generating plasma, within a range equal to or greater than 1 Pa and less than 5 Pa; and applying a bias voltage of frequency equal to or greater than 800 kHz and less than 4 MHz as a bias voltage to an etched material in which the conductive material is layered on the dielectric material, and performing etching, wherein the dielectric material is a ferroelectric material and the conductive material is a noble metal material.

### CROSS REFERENCE TO RELATED APPLICATIONS

This application is a continuation of International Application No. PCT/JP2012/062368 filed on May 15, 2012, which claims priority to Japanese Application No. 2011-113627 filed on May 20, 2011. The entire contents of each of the above applications are hereby incorporated by reference.

### BACKGROUND OF THE INVENTION

1. Field of the Invention

The present invention relates to a dry etching method and a device manufacturing method. Specifically, the present invention relates to a dry etching technique suitable to patterning processing of metal materials in a laminate structure in which the metal materials are layered in a dielectric material, and a device manufacturing technique to manufacture an actuator, a sensor and other various circuit elements by applying this.

2. Description of the Related Art

Japanese Patent Application Laid-Open No. 2000-133783 (hereinafter referred to as PTL 1) suggests a method of being able to form a minute pattern at high dimension accuracy without leaving a reaction product of low vapor pressure on a sidewall of the pattern in a technique of patterning a conductive film of an iridium (Ir) type, in particular, an IrO₂ film by dry etching using a resist mask (etching-resistant mask layer). To be more specific, at the time of patterning the IrO₂ film on the dielectric film by the dry etching using the resist mask, an etching gas that contains a chlorine gas as a principal component and contains oxygen as an additive gas is used to decrease selection ratio of the IrO₂ film against resist and cause the sidewall of the resist mask to retreat. As a result of this, there is provided a method of removing a sidewall adhesion film that adheres to a pattern sidewall.

Japanese Patent Application Laid-Open No. 2001-271182 (hereinafter referred to as PTL 2) discloses using an etching gas that contains an active gas and a fluorine type gas in a dry etching method of patterning a metallic thin film of iridium by the use of a resist mask.

Japanese Patent Application Laid-Open No. 2006-294847 (hereinafter referred to as PTL 3) provides a dry etching method without sidewall adhesion by applying the low-frequency bias power to a film including noble metal under high vacuum and high density plasma, using the mixed gas of a halogen gas and inactive gas as an etching processing gas in a dry etching method of a film including noble metal.

### SUMMARY OF THE INVENTION

For example, a piezoelectric body used for a piezoelectric element, a noble metal used for an electrode thereof and the like are called hard etching materials, which are hard to be processed by dry etching. Although such a material is generally to subjected to etching processing using the mixed gas of a halogen gas and inactive gas as described in PTL 2 and PTL 3, there are problems that: (1) the etching speed is slow; (2) the selection ratio of a mask such as resist is low; and (3) selection ratio with a ground film is low.

Specifically, in the case of a piezoelectric element having a laminate structure in which a silicon dioxide film as an insulator film, a lower electrode, a piezoelectric body and an upper electrode are layered in order on a silicon substrate, there are problems that selection ratio with the piezoelectric body is low and the etching rate is slow at the time of patterning this layered upper electrode.

However, in PTL 1, there is no description related to selection ratio with a dielectric that is a ground film. In PTL 1, although etching stop is performed by OES (Optical Emission Spectroscopy) at the time of Ir etching, when the selection ratio with a ground film is low, there is a problem that the trim amount of the dielectric that is the ground film increases and a defective shape is caused. Moreover, when the trimming is caused in a dielectric layer, characteristic of device is degraded. Even in PTL 2 and PTL 3, there is no description about the selection ratio with the ground film.

When the inventors of the present invention actually conducted experiments, in a case where an electrode material such as Ir and Pt on a piezoelectric body was etched with adopting an etching method by low-frequency bias application using chlorine and inactive gas or using chlorine and oxygen as an etchant under a condition of high vacuum, it was not possible to acquire sufficient selection ratio with a piezoelectric body that is a ground film. According to the result of the experiments, the selection ratio was about 2 though oxygen was added.

The above-mentioned problem is not limited to the piezoelectric element but is common in what has a structure in which a metal material is layered on a dielectric material.

The present invention is made considering such circumstances and its object is to provide a dry etching method capable of increasing selection ratio between a metal material and a dielectric that is a ground thereof, and improving the etching speed (etching rate), and a device manufacturing method to which this is applied.

One aspect of the present invention relates to a dry etching method of etching a conductive material layered on a dielectric material, comprising: using a mixed gas including a halogen gas and an oxygen gas as an etching gas, a mixing ratio of the oxygen gas in the mixed gas being equal to or greater than 30% and equal to or less than 60%; setting a gas pressure in a chamber at a time of supplying the mixed gas into the chamber and generating plasma, within a range equal to or greater than 1 Pa and less than 5 Pa; and applying a bias voltage of frequency equal to or greater than 800 kHz and less than 4 MHz as a bias voltage to an etched material in which the conductive material is layered on the dielectric material, and performing etching.

Another aspect of the present invention relates to a device manufacturing method, patterning the conductive material by etching with the use of the above-mentioned dry etching method, and manufacturing a device having a structure in which an electrode made of the conductive material and the dielectric material are layered.

Another aspect of the present invention relates to a device manufacturing method, including: a first electrode formation step of forming a first electrode with a first conductive material on a substrate; a dielectric layer formation step of layering a dielectric material on the first electrode; a second electrode formation step of forming a second electrode with a second conductive material on the dielectric material; and a patterning step of etching the second conductive material forming the second electrode with the use of the above-mentioned dry etching method and patterning the second electrode.

Other aspects of the present invention are clarified by this specification and description of the drawings.

According to the present invention, etching processing is possible in which the etching rate is high and the selection ratio with a dielectric material that is a ground layer is secured.

### BRIEF DESCRIPTION OF THE DRAWINGS

FIG. 1 is an explanatory diagram illustrating a manufacturing process of a piezoelectric element.

FIG. 2 is a configuration diagram of a dry etching apparatus.

FIG. 3 is a table in which the results of Comparative Examples 1 to 3 and an Example are summarized.

FIG. 4 is a graph showing relationship between the mixing ratio of the oxygen gas and the etching rate by Comparative Example 1.

FIG. 5 is a graph showing relationship between the mixing ratio of the oxygen gas and selection ratio (Ir/PZT) by Comparative Example 1.

FIG. 6 is a graph showing relationship between the mixing ratio of the oxygen gas and the etching rate by Comparative Example 2.

FIG. 7 is a graph showing relationship between the mixing ratio of the oxygen gas and the selection ratio (Ir/PZT) by Comparative Example 2.

FIG. 8 is a graph showing relationship between the mixing ratio of the oxygen gas and the etching rate by Comparative Example 3.

FIG. 9 is a graph showing relationship between the mixing ratio of the oxygen gas and the selection ratio (Ir/PZT) by Comparative Example 3.

FIG. 10 is a graph showing relationship between the mixing ratio of the oxygen gas and the etching rate by the Example.

FIG. 11 is a graph showing relationship between the mixing ratio of the oxygen gas and the selection ratio (Ir/PZT) by the Example.

### DETAILED DESCRIPTION OF THE PREFERRED EMBODIMENTS

In the following, embodiments of the present invention are described in detail according to the accompanying drawings.

### [Manufacturing Process Example of Piezoelectric Element]

Here, the manufacturing process of piezoelectric elements is exemplified, and a dry etching method according to an embodiment of the present invention and an upper electrode patterning step using this are explained.

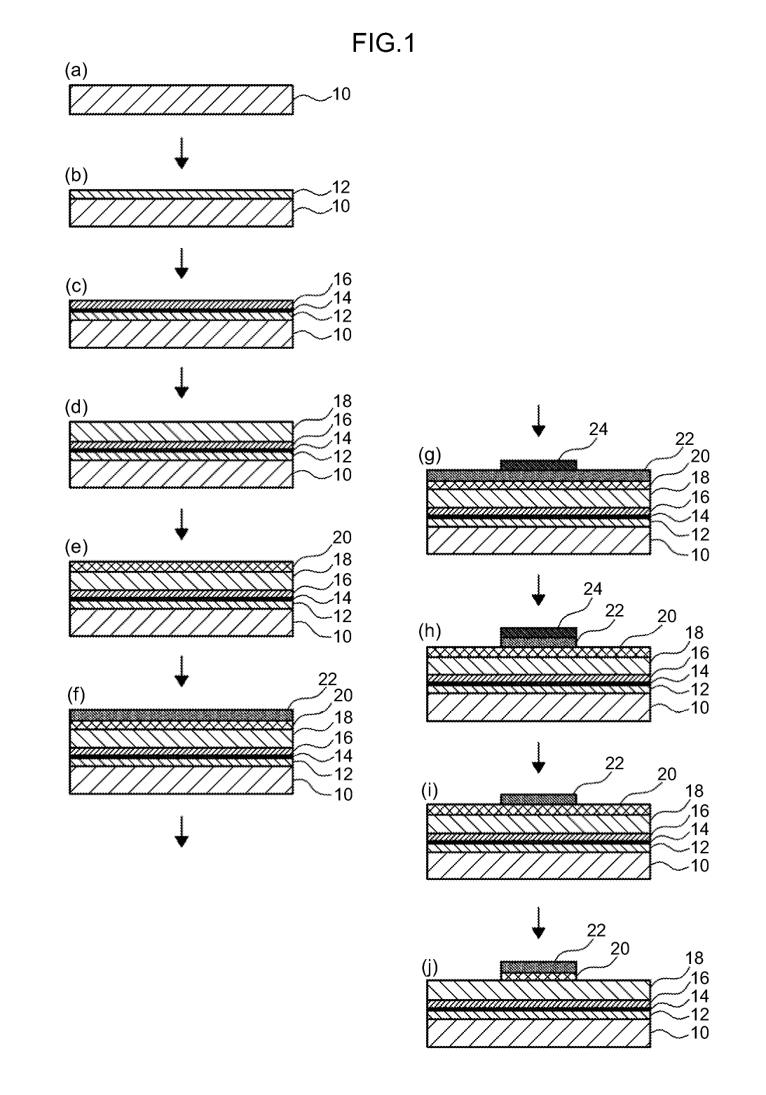

FIG. 1 is an explanatory diagram illustrating a manufacturing process of a piezoelectric element.

### (Step 1): Substrate Preparation Step

First, a silicon (Si) substrate 10 is prepared as illustrated in FIG. 1(a).

### (Step 2): Insulation Film Formation Step

Next, an insulation film (for example, an oxide film such as SiO₂) 12 is formed on this silicon substrate 10 (FIG. 1(b)). As an example, a silicon oxide film is formed by the CVD (Chemical Vapor Deposition), sputtering, vapor deposition or thermal oxidation method.

### (Step 3): Lower Electrode Formation Step

Next, a contact layer (for example, Ti layer or the like) 14 is formed on the insulation film 12, and a noble metal film corresponding to a lower electrode 16 is formed over the contact layer 14 (FIG. 1(c)). The lower electrode 16 is formed with Pt (platinum), Ir (iridium), or Ru (ruthenium) that is a noble metal material or an oxide film thereof. The lower electrode 16 can be formed by the sputtering method and the CVD method, and so on.

### (Step 4): Piezoelectric Body Formation Step

Next, a piezoelectric body 18 is formed on the lower electrode 16 as illustrated in FIG. 1(d). The piezoelectric body 18 can be formed with lead zirconate titanate (PZT) that is a ferroelectric, and so on, and can be formed by the sputtering method, the CVD method and the sol-gel method, and so on. Here, not only PZT but also lead lanthanum zirconate titanic (PLZT) and “PZTN” replacing part of Ti of PZT with Nb can be used as a material of the piezoelectric body 18.

### (Step 5): Upper Electrode Formation Step

Next, a noble metal film corresponding to an upper electrode 20 is formed over the piezoelectric body 18 (FIG. 1(e)). The upper electrode 20 can be formed with Pt, Ir, Ru, or an oxide film thereof (PtOx, IrOx, RuOx), and can be formed by the sputtering method and the CVD method, and so on. Here, PtOx is the collective term of oxidation products of platinum, and “x” designates a positive number showing the ratio of Pt and O. The same applies to IrOx and RuOx, that is, IrOx is the collective term of oxidation products of iridium and RuOx is the collective term of oxidation products of ruthenium.

### (Step 6): Hard Mask Formation Step

Next, a hard mask 22 covering the upper electrode 20 is formed (FIG. 1(f)). The hard mask 22 can be formed using a silicon oxide film, a silicon nitride film, an organic SOG (Spin on Glass) film, an inorganic SOG film, or metal such as Ti, Cr, Al and Ni. Here, as the hard mask 22, the silicon oxide film is formed by the TEOS (Tetra Ethyl Ortho Silicate)-CVD method.

### (Step 7): Resist Mask Formation Step

Next, a soft bake is performed after a resist 24 is formed on the layer of the hard mask 22 by the spin coat method or the like, and a post bake is performed after exposure and development. Here, instead of the post bake, hardening treatment (UV cure) by ultraviolet light irradiation may be performed. Thus, the resist 24 for upper electrode patterning is patterned (FIG. 1(g)).

### (Step 8): Hard Mask Patterning Step

In a case where the hard mask 22 is a silicon oxide film, the hard mask 22 is patterned by the dry etching method (FIG. 1(h)).

### (Step 9): Resist Removal Step

After that, processing of removing the resist 24 used in the above-mentioned patterning step of the hard mask 22 by the use of the ashing method or dedicated peeling liquid is performed (FIG. 1(i)).

### (Step 10): Upper Electrode Patterning Step

The patterning of the upper electrode 20 is performed by the dry etching method to which an aspect of the present invention is applied (FIG. 1(j)). Important points in the dry etching of the upper electrode 20 are that the etching rate is high-speed, the mask selection ratio and the selection ratio with a dielectric (PZT in this example) that is a ground film are high, and the etching shape is good. Especially, there is a problem that ground film selection ratio decreases when the etching rate is made high-speed.

The dry etching method according to the present embodiment described below in more detail is a dry etching method in which the etching rate is high speed and the selection ratio with the ground film can be sufficiently secured.

### <Structure Example of Dry Etching Apparatus>

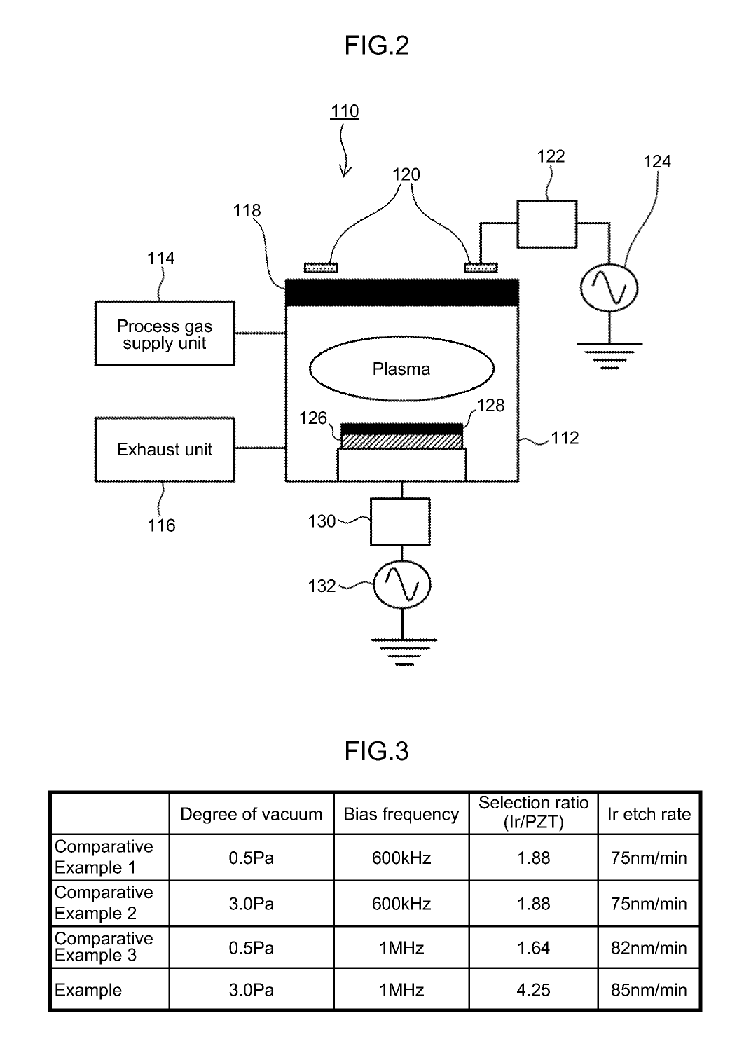

FIG. 2 is a configuration diagram of a dry etching apparatus that uses a dry etching method according to the present embodiment. As for a dry etching apparatus 110, for example, an apparatus of the inductive coupling plasma (ICP) scheme is used. In addition, a scheme using a plasma source such as the helicon wave plasma (HWP), the electron cyclotron resonance (ECR) plasma and the surface wave plasma (SWP) can also be applied to the dry etching apparatus 110.

The dry etching apparatus 110 includes a process gas supply unit 114 that supplies a process gas (etching gas) into a chamber 112 (vacuum case), an exhaust unit 116 that exhausts the gas in the chamber 112 and a pressure adjustment unit (not illustrated) that performs pressure adjustment in the chamber 112. By supplying the process gas from the process gas supply unit 114 into the chamber 112 while performing exhaust from the exhaust unit 116, the pressure adjustment in the chamber 112 is performed. When the aspect according to the present invention is implemented, the mixed gas of a chlorine gas and oxygen gas is used as a process gas (etching gas).

A dielectric window 118 is installed in an upper surface of the chamber 112 in a hermetically-sealed manner, and, in addition, an antenna 120 of a loop coil shape is installed above the dielectric window 118 (atmosphere side). A high-frequency power source (RF power source) 124 for plasma generation is connected to the antenna 120 through a matching circuit (matching box) 122. The frequency of the high-frequency power source 124 can use a frequency band, which is equal to or greater than 13.56 MHz and equal to or less than 60 MHz, and uses, for example, 13.56 MHz. Moreover, the high-frequency power source 124 may be pulse-driven.

A stage 126 is installed in the chamber 112. A substrate cooling mechanism (not illustrated) including an electrostatic chuck or clamp is installed in the stage 126 and a substrate 128 that is an etched material is placed on the stage 126. A low-frequency power source 132 for bias application is connected to the stage 126 through a matching circuit 130. 800 kHz or more and 4 MHz or less is used as the frequency of the low-frequency power source 132. Preferably, the frequency of the low-frequency power source 132 may be set equal to or greater than 900 kHz and equal to or less than 2 MHz. Especially, the frequency before or after 1 MHz is preferable as the frequency of the low-frequency power source 132.

Moreover, in a case where the bias supply is pulse-driven, pulse driving means only has to be installed in the bias supply. In addition, in a case where the bias supply is used by pulse drive, it only has to use means for synchronizing the power source (the high-frequency power source 124) of the antenna 120 (for plasma generation) with the pulse period of the bias supply (the low-frequency power source 132).

The upper electrode 20 explained in FIG. 1(j) is etched using the dry etching apparatus 110 in FIG. 2. Specifically, it is performed as follows. That is, a substrate (laminate structure illustrated in FIG. 1(i)) as an etched material is placed on the stage 126 in the chamber 112 of the dry etching apparatus 110 illustrated in FIG. 2. Next, after keeping a vacuum state in the chamber 112, the mixed gas of the chlorine gas and the oxygen gas is supplied from the process gas supply unit 114 as an etching gas while exhaust is performed by the exhaust unit 116, and pressure adjustment is performed such that a predetermined gas pressure (for example, a predetermined value within a range equal to or greater than 1 Pa and equal to or less than 5 Pa, and this example assumes 3 Pa) is maintained in the chamber 112. Next, required power (for example, power of 500 W) is supplied from the high-frequency power source 124 to the antenna 120, and high-density plasma is generated in the chamber 112. At this time, prescribed power (for example, power of 200 W) is applied from the low-frequency power source 132 to the stage 126 that retains an etched material.

As a result of this, in the electrode film of the upper electrode 20 illustrated in FIG. 1(i), a part that is not covered by the hard mask 22 is removed by etching, and the upper electrode 20 is patterned while a part that is covered by the hard mask 22 is left (FIG. 1(j)). After that, removing the hard mask 22 allows a piezoelectric element having a laminate structure of the lower electrode 16, the piezoelectric body 18 and the upper electrode 20 to form on the silicon substrate 10.

### <Etching Conditions>

To understand a preferable condition when the upper electrode 20 is etched, experiments were conducted with changing conditions of the mixing ratio (oxygen partial pressure) of the oxygen gas in the etching gas, the gas pressure (degree of vacuum) and the frequency of the bias supply (the low-frequency power source 132).

In Comparative Examples 1 to 3 and an Example shown below, it is assumed that the power of an RF power source for an antenna (the high-frequency power source 124) is 500 W, the power of a power source for bias (the low-frequency power source 132) is 200 W and the power conditions are common. Subsequently, under the conditions in which a combination of the gas pressure and the bias frequency is changed, the selection ratio is calculated from the etching rate of Ir and the etching rate of PZT that is a ground film with an assumption that the additive amount of the oxygen gas with respect to the chlorine gas of the etching gas (the mixing ratio of the oxygen gas to the whole) is variable.

FIG. 3 summarizes the results of Comparative Examples 1 to 3 and the Example.

### Comparative Example 1

Comparative Example 1 uses a condition of 600 kHz as the frequency of the power source for bias (the low-frequency power source 132). With an assumption that the degree of vacuum (gas pressure) in the chamber 112 is 0.5 Pa, the flow ratio of the oxygen in the etching gas (the mixed gas of the chlorine and the oxygen) is varied and Ir on the PZT film is etched. The conditions of the bias frequency and the gas pressure in Comparative Example 1 are conditions that are generally used as etching conditions of noble metal materials such as Ir and Pt.

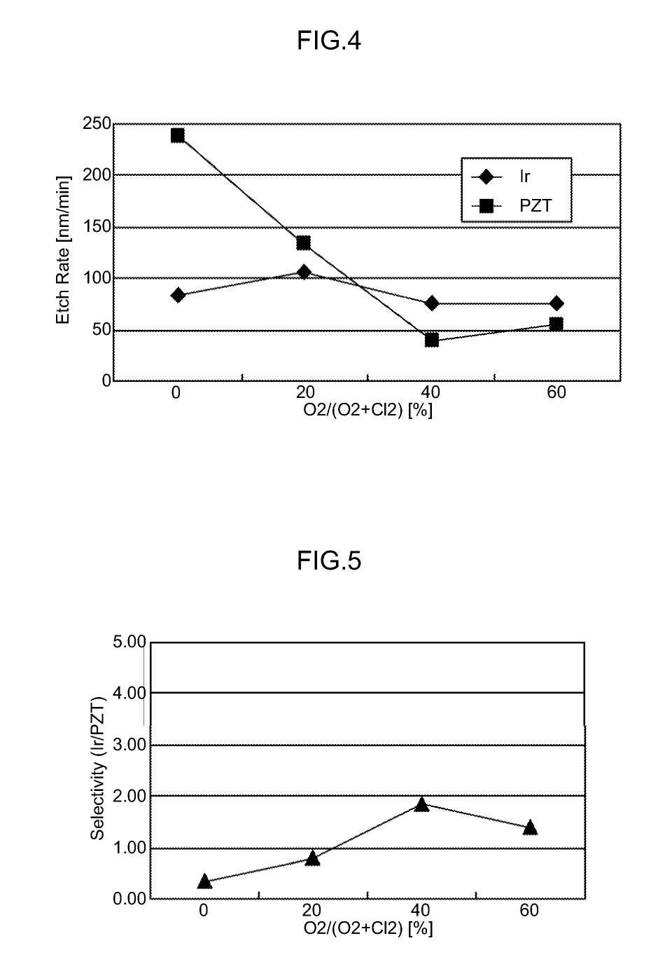

FIGS. 4 and 5 are graphs showing the results at the time of etching Ir on the conditions of Comparative Example 1. FIG. 4 is a graph showing relationship between the mixing ratio of the oxygen gas in the mixed gas and the respective etching rates of Ir and PZT. In FIG. 4, the horizontal axis shows the mixing ratio of the oxygen gas in the mixed gas of the chlorine gas and the oxygen gas, and the vertical axis shows the etching rate.

FIG. 5 is a graph showing relationship between the mixing ratio of the oxygen gas in the mixed gas and the selection ratio (Ir/PZT). In FIG. 5, the horizontal axis shows the mixing ratio of the oxygen gas in the mixed gas of the chlorine gas and the oxygen gas, and the vertical axis shows the selection ratio.

As illustrated in FIGS. 4 and 5, in the case of Comparative Example 1, the etching rate is relatively high-speed, 70 to 105 nm/min. However, the selection ratio with PZT that is the ground film is low, about 0.2 to 1.8, 1.88 at the highest, and the etching rate at that time is 75 nm/min. That is, according to the conditions of Comparative Example 1, the etching rate is high-speed, 75 nm/min, but the selection ratio is low, 2 or less.

### Comparative Example 2

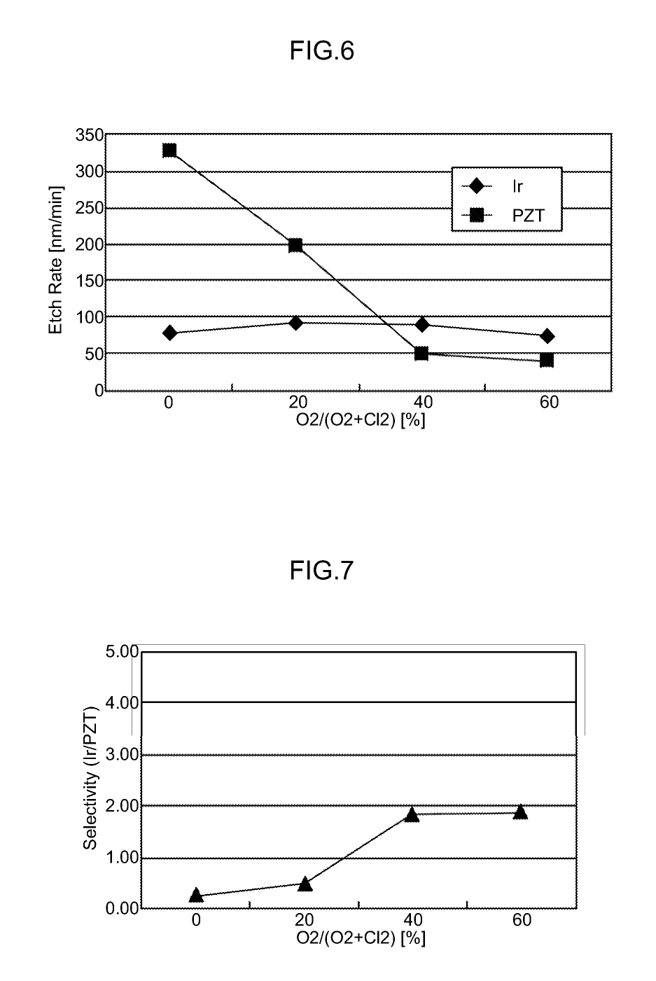

In Comparative Example 2, Ir is etched with an assumption that the degree of vacuum is 3.0 Pa and the other conditions are the same as Comparative Example 1. FIGS. 6 and 7 are graphs showing results at the time of etching Ir on the conditions of Comparative Example 2. FIG. 6 is a graph showing relationship between the mixing ratio of the oxygen gas in the mixed gas and the respective etching rates of Ir and PZT, and FIG. 7 is a graph showing relationship between the mixing ratio of the oxygen gas in the mixed gas and the selection ratio (Ir/PZT).

As illustrated in FIGS. 6 and 7, in the case of Comparative Example 2, the etching rate is relatively high-speed, 70 to 95 nm/min. However, selection ratio with PZT that is the ground film is low, about 0.2 to 1.8, 1.88 at the highest, and the etching rate at that time is 75 nm/min. That is, according to the conditions of Comparative Example 2, the etching rate is high-speed, 75 nm/min, but the selection ratio is low, 2 or less.

### Comparative Example 3

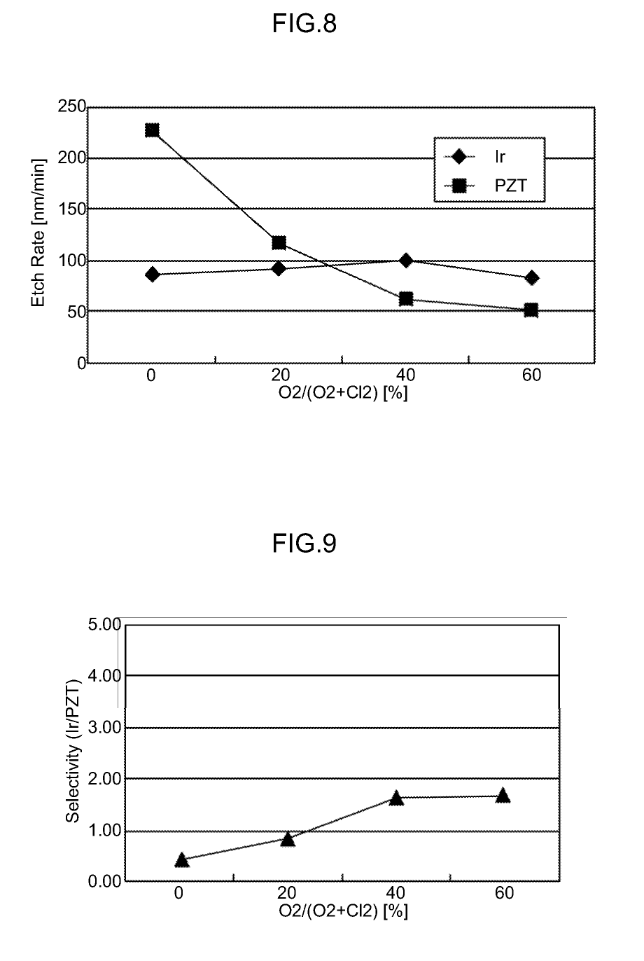

In Comparative Example 3, Ir is etched with an assumption that the frequency of the power source for bias is set to 1 MHz and the other conditions are the same as Comparative Example 1. FIGS. 8 and 9 are graphs showing results at the time of etching Ir on the conditions of Comparative Example 3. FIG. 8 is a graph showing relationship between the mixing ratio of the oxygen gas in the mixed gas and the respective etching rates of Ir and PZT, and FIG. 9 is a graph showing relationship between the mixing ratio of the oxygen gas in the mixed gas and the selection ratio (Ir/PZT).

As illustrated in FIGS. 8 and 9, in the case of Comparative Example 3, the etching rate is relatively high-speed, 60 to 80 nm/min. However, the selection ratio with PZT that is the ground film is low, about 0.2 to 1.6, 1.6 at the highest, and the etching rate at that time is 82 nm/min. That is, according to the conditions of Comparative Example 3, the etching rate is high-speed, 75 nm/min, but the selection ratio is low, 2 or less.

### Example

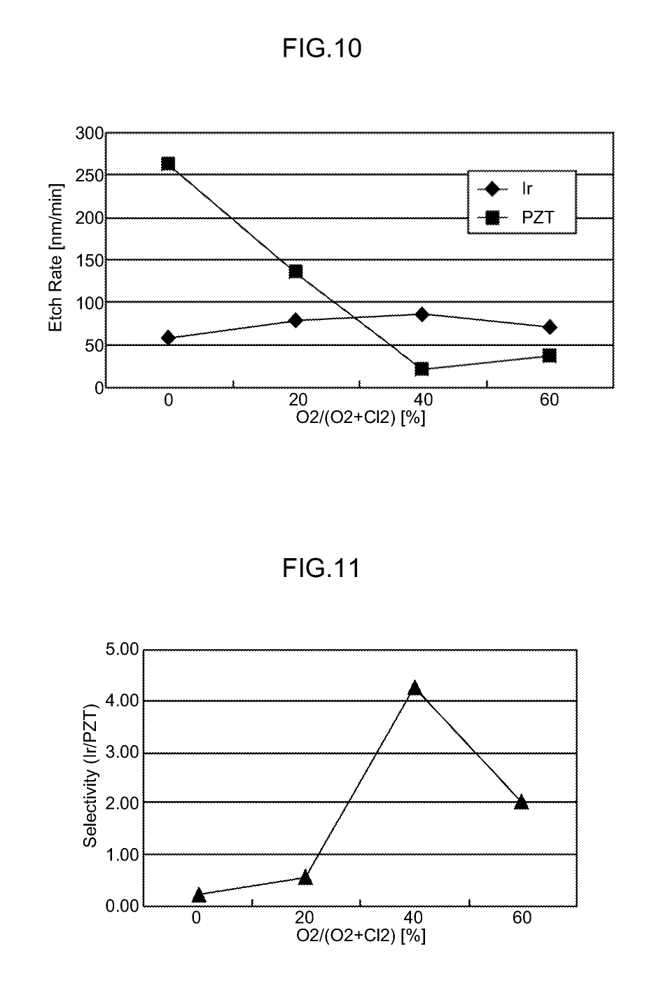

As an Example, Ir is etched under conditions that the frequency of the power source for bias is set to 1 MHz, the degree of vacuum is 3.0 Pa, the mixed gas of chlorine and oxygen is used, the flow ratio is variable, the high-frequency (RF) power source is 500 W and the power source for bias (low frequency) is 200 W. FIGS. 10 and 11 are graphs showing results at the time of etching Ir on the conditions of this Example. FIG. 10 is a graph showing relationship between the mixing ratio of the oxygen gas in the mixed gas and the respective etching rates of Ir and PZT, and FIG. 11 is a graph showing relationship between the mixing ratio of the oxygen gas in the mixed gas and the selection ratio (Ir/PZT). As illustrated in FIGS. 10 and 11, the etching rate is relatively high-speed, 55 to 85 nm/min. Moreover, the selection ratio with PZT that is the ground film contains a high value, about 0.2 to 4.25. The highest value is 4.25 and the etching rate at that time is 85 nm/min.

In FIG. 11, a high selection ratio equal to or greater than 2 can be realized within the range of 30% to 60% of the mixing ratio of the oxygen gas and the etching rate of Ir is high-speed (see FIG. 10). The best condition is when the mixing ratio of the oxygen gas is 40%, and, according to the conditions of this Example, the etching rate is high-speed, 85 nm/min, but the selection ratio is high, 4 or more.

As understood by comparing Comparative Examples 1 to 3 and the Example, it is difficult to find good conditions by separately adjusting conditions of the bias frequency, the gas pressure and the mixing ratio of the oxygen gas, but their appropriate combination realizes good etching.

### <Consideration of Preferable Etching Conditions>

[1] Regarding the bias frequency, in general, the frequency of the power source for bias (bias frequency) contributes to the energy amount of ion. When the bias frequency is less than 800 kHz as Comparative Example 1, the ion energy is high, etching of a ferroelectric (PZT) that is a ground film progresses and it is not possible to acquire a sufficient selection ratio. In contrast, when the bias frequency is equal to or greater than 4 MHz, the ion energy is low and it is not possible to etch noble metal materials at high speed.

In view of the above, preferably, the bias frequency is equal to or greater than 800 kHz and less than 4 MHz, and, more preferably, it is nearly 1 MHz. As the range of “nearly” in the case of nearly 1 MHz, it is possible to set an appropriate allowable range within a range in which it is possible to acquire a suitable function and effect. For example, when ±15% (±150 kHz) is set to the allowable range, nearly 1 MHz is a range from 850 kHz to 1.15 MHz. When ±10% (±100 kHz) is set to the allowable range, nearly 1 MHz is a range from 900 kHz to 1.1 MHz. When ±5% (±50 kHz) is set to the allowable range, nearly 1 MHz is a range from 950 kHz to 1.05 MHz.

[2] Regarding the gas pressure (etching pressure), in a case where the etching pressure is less than 1 Pa, the ion energy is high, the etching rate of the ferroelectric (PZT) that is the ground film is fast and it is not possible to acquire a sufficient selection ratio. In contrast, in case of 5 Pa or more, since a lot of radicals are generated, the ion content is little and the ion energy is low, it is not possible to sufficiently etch noble metal materials. In view of the above, preferably, the etching pressure (which may be referred to as “processing pressure”) is equal to or greater than 1 Pa and less than 5 Pa, and, more preferably, it is nearly 3 Pa. As the range of “nearly” in the case of nearly 3 Pa, it is possible to set an appropriate allowable range within a range in which it is possible to acquire a suitable function and effect. For example, when ±0.5 Pa is set to the allowable range, nearly 3 Pa is in a range of 3 Pa±0.5 Pa, and, when ±10% is set to the allowable range, it is in a range of 3 Pa±0.3 Pa.

[3] Regarding an etching gas, the mixed gas of chlorine and oxygen is used as the etching gas. In the case of only the chlorine, the etching rate of a ferroelectric (for example, PZT) that is a ground film is fast and it is not possible to acquire the selection ratio. By adding the oxygen gas, oxidization reaction of an etchant is performed. That is, Ir that is a noble metal material is oxidized, an oxidation product of IrOx is generated and the etching rate improves. Here, IrOx is the collective term of oxidation products of iridium, and “x” designates a positive number showing the ratio of Ir and O. Meanwhile, as for an oxidation product such as a ferroelectric, the etching rate decreases by addition of the oxygen gas. Especially, in a case where the addition ratio (oxygen partial pressure) of oxygen is equal to or greater than 30%, the effect is dramatically shown (see FIG. 11). However, when the oxygen addition amount exceeds 60%, the chlorine amount that is a main etchant decreases and the etching rate of Ir decreases.

In view of the above, it is desirable that addition amount (oxygen partial pressure) in the case of adding oxygen to chlorine is 30 to 60%. More preferably, it is desired that the oxygen addition amount (oxygen partial pressure) is 35% to 50% from the viewpoint that a ground selection ratio of 3 or more is realized, and, especially, it is desirable to be nearly 40%. As the range of “nearly” in the case of nearly 40%, it is possible to set an appropriate allowable range within a range in which it is possible to acquire a suitable function and effect. For example, when ±5% is set to the allowable range, nearly 40% is in a range from 35% to 45%. Alternatively, the range of “nearly” may also be defined from the viewpoint of the addition amount of oxygen by which the selection ratio is equal to or greater than 4, from the graph of FIG. 11.

By combinations of the conditions of the bias frequency, gas pressure and etching gas explained in above-mentioned [1] to [3], an intended good etching result is acquired.

Especially, nearly 1 MHz is used for the bias frequency, oxygen is added to chlorine as an etching gas, and, on conditions that the oxygen partial pressure is 40% and the degree of vacuum is about 3 Pa, etching processing is possible in which the etching rate of Ir is high-speed and a sufficient selection ratio, that is, a selection ratio equal to or greater than 4 with respect to PZT that is a ground film is secured.

<Regarding Availability of Gas Type Other than Chlorine Gas>

In the above-mentioned embodiment, although the mixed gas of the chlorine gas and the oxygen gas is used, at the time of implementing the present invention, it is also possible to use another halogen gas instead of the chlorine gas.

### <Regarding Electrical Power (Power) of High-Frequency Power Source>

Although 500 W is exemplified as power supplied from the high-frequency power source 124 to the antenna 120, conditions of the power can be arbitrarily changed. Depending on an increase or decrease of power, in the graphs of the etching rates illustrated in respective FIGS. 4, 6, 8 and 10, Ir and PZT merely shift in the vertical direction as a whole (the value of the etching rate increases or decreases), and the power conditions have little influence on the selection ratio.

### <Usage of Piezoelectric Element>

A piezoelectric element manufactured in the process described in FIG. 1(i) can be used for various usages such as an actuator and a sensor. For example, in a case where it is used as a piezoelectric actuator that causes droplet ejection pressure in an ink jet head, it is possible to form a pressure chamber (ink chamber) by processing the layer of the silicon substrate 10 in FIG. 1(i). Part of the silicon substrate 10 functions as a vibration plate, and a unimorph piezoelectric actuator is formed by a structure in which the lower electrode 16, the piezoelectric body 18 and the upper electrode 20 are layered in the vibration plate. That is, FIG. 1 can be understood as a manufacturing process of the actuator. Moreover, the present invention is applicable to production of not only an actuator of the unimorph type but also production of actuators of various schemes such as a bimorph actuator.

### <Regarding Application to Various Devices>

The application range of the present invention is not limited to the piezoelectric device exemplified above and is widely applicable to various devices having a structure in which a dielectric and a conductive material (electrode) are layered. These devices include various devices such as a capacitor, an acceleration sensor, a temperature sensor, a memory device and a pyroelectric device.

Also, the present invention is not limited to the embodiment described above and many changes can be made by a person who has normal knowledge of the field in the technical idea of the present invention.

### <Appendix: Regarding Aspects of Disclosed Invention>

As understood from the description of the embodiment of the invention explained above in detail, this specification contains at least the disclosure of various technical ideas including the following inventions.

### (Aspect 1)

A dry etching method of etching a conductive material layered on a dielectric material, comprising: using a mixed gas including a halogen gas and an oxygen gas as an etching gas; setting a mixing ratio of the oxygen gas in the mixed gas to be equal to or greater than 30% and equal to or less than 60%; setting a gas pressure in a chamber at a time of supplying the mixed gas into the chamber and generating plasma, within a range equal to or greater than 1 Pa and less than 5 Pa; and applying a bias voltage of frequency equal to or greater than 800 kHz and less than 4 MHz as a bias voltage to an etched material in which the conductive material is layered on the dielectric material, and performing etching.

According to this aspect, it is possible to secure the selection ratio with a dielectric material that is the ground, and make the etching speed of a conductive material high-speed.

### (Aspect 2)

The dry etching method according to Aspect 1, wherein the halogen gas is a chlorine gas.

An aspect is preferable in which mixed gas of chlorine gas and oxygen gas is used as etching gas.

### (Aspect 3)

The dry etching method according to Aspect 1 or 2, wherein the dielectric material is a ferroelectric material and the conductive material is a noble metal material.

The dry etching method of this aspect is means for being able to etch a noble metal material excellently in a structure in which the noble metal material is layered on a ferroelectric material.

### (Aspect 4):

There is provided the dry etching method according to any of Aspects 1 to 3, wherein the dielectric material includes PZT, PLZT or PZTN.

As a dielectric material, it is possible to use PZT, PLZT and PZTN.

### (Aspect 5)

The dry etching method according to any of Aspects 1 to 4, wherein the conductive material includes any of metal materials of Ru, Ir and Pt, or any of metal oxides of RuOx, IrOx and PtOx which are oxidation products of the metal materials (where x designates a positive number) or a combination of these materials.

The dry etching method of this aspect is means for etching noble metals such as Ru, Ir and Pt or metal oxides thereof excellently.

### (Aspect 6)

The dry etching method according to any of Aspects 1 to 5, wherein: the mixing ratio of the oxygen gas in the mixed gas is in a range of 40%±5%; the gas pressure is in a range of 3 Pa±0.5 Pa; and the frequency of the bias voltage is in a range of 1 MHz±100 kHz.

Such an aspect is an especially effective condition in the point that both the speed-up of the etching rate and a sufficient selection ratio are established.

### (Aspect 7)

A device manufacturing method, comprising: patterning the conductive material by etching with the use of the dry etching method according to any of Aspects 1 to 6; and manufacturing a device having a structure in which an electrode made of the conductive material and the dielectric material are layered.

According to this aspect, at the time of patterning of an electrode (conductive material), occurrence of a defective shape or the like is suppressed. As a result of this, it is possible to achieve yield improvement and produce a device with stable characteristics.

### (Aspect 8)

The device manufacturing method according to Aspect 7, wherein the device is an actuator having a structure in which the dielectric material lies between a first electrode and a second electrode.

This aspect provides is effective means as a manufacturing method of an actuator.

### (Aspect 9)

A device manufacturing method, comprising: a first electrode formation step of forming a first electrode with a first conductive material on a substrate; a dielectric layer formation step of layering a dielectric material on the first electrode; a second electrode formation step of forming a second electrode with a second conductive material on the dielectric material; and a patterning step of etching the second conductive material forming the second electrode with the use of the dry etching method according to any of Aspects 1 to 6, and patterning the second electrode.

According to this aspect, at the time of patterning of the second electrode (second conductive material), occurrence of a defective shape or the like is suppressed. As a result of this, it is possible to achieve yield improvement and produce a device with stable characteristics.

What is claimed is:

1. A dry etching method of etching a conductive material layered on a dielectric material, comprising:
using a mixed gas including a halogen gas and an oxygen gas as an etching gas, a mixing ratio of the oxygen gas in the mixed gas being equal to or greater than 30% and equal to or less than 60%;
setting a gas pressure in a chamber at a time of supplying the mixed gas into the chamber and generating plasma, within a range equal to or greater than 1 Pa and less than 5 Pa; and
applying a bias voltage of frequency equal to or greater than 800 kHz and less than 4 MHz as a bias voltage to an etched material in which the conductive material is layered on the dielectric material, and performing etching, wherein the dielectric material is a ferroelectric material and the conductive material is a noble metal material.

2. The dry etching method according to claim 1, wherein the halogen gas is a chlorine gas.

3. The dry etching method according to claim 1, wherein the dielectric material includes PZT, PLZT or PZTN.

4. The dry etching method according to claim 2, wherein the dielectric material includes PZT, PLZT or PZTN.

5. The dry etching method according to claim 1, wherein the conductive material includes any of metal materials of Ru, Ir and Pt, or any of metal oxides of RuOx, IrOx and PtOx which are oxidation products of the metal materials (where x designates a positive number) or a combination of these materials.

6. The dry etching method according to claim 2, wherein the conductive material includes any of metal materials of Ru, Ir and Pt, or any of metal oxides of RuOx, IrOx and PtOx which are oxidation products of the metal materials (where x designates a positive number) or a combination of these materials.

7. The dry etching method according to claim 3, wherein the conductive material includes any of metal materials of Ru, Ir and Pt, or any of metal oxides of RuOx, IrOx and PtOx which are oxidation products of the metal materials (where x designates a positive number) or a combination of these materials.

8. The dry etching method according to claim 4, wherein the conductive material includes any of metal materials of Ru, Ir and Pt, or any of metal oxides of RuOx, IrOx and PtOx which are oxidation products of the metal materials (where x designates a positive number) or a combination of these materials.

9. The dry etching method according to claim 1, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

10. The dry etching method according to claim 2, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

11. The dry etching method according to claim 3, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

12. The dry etching method according to claim 4, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

13. The dry etching method according to claim 5, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

14. The dry etching method according to claim 6, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

15. The dry etching method according to claim 7, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

16. The dry etching method according to claim 8, wherein:
the mixing ratio of the oxygen gas in the mixed gas is in a range of 40%±5%;
the gas pressure is in a range of 3 Pa±0.5 Pa; and
the frequency of the bias voltage is in a range of 1 MHz±100 kHz.

17. A device manufacturing method, comprising: patterning the conductive material by etching with the use of the dry etching method according to claim 1; and
manufacturing a device having a structure in which an electrode made of the conductive material and the dielectric material are layered.

18. The device manufacturing method according to claim 17, wherein the device is an actuator having a structure in which the dielectric material lies between a first electrode and a second electrode.

19. A device manufacturing method, comprising:
a first electrode formation step of forming a first electrode with a first conductive material on a substrate;
a dielectric layer formation step of layering a dielectric material on the first electrode;
a second electrode formation step of forming a second electrode with a second conductive material on the dielectric material; and
a patterning step of etching the second conductive material forming the second electrode with the use of the dry etching method according to claim 1, and patterning the second electrode.
